(19) United States
(12) Patent Application Publication
(10) Pub. No.: US 2009/0079054 A1
(43) Pub. Date: Mar. 26, 2009

(54) Semiconductor device, structure of mounting the same, and method of removing foreign matter from the same

(75) Inventor: Nobuaki Asai, Hashima-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/232,688

(22) Filed: Sep. 23, 2008

(30) Foreign Application Priority Data
Sep. 26, 2007 (JP) 2007-249758

(51) Int. Cl. H01L 23/26; H01L 21/50

(52) U.S. Cl. 257/682; 438/120; 257/E23.137; 257/E21.499

(57) ABSTRACT

A semiconductor device includes a package defining an enclosed inner space, a semiconductor chip having a movable portion on one side and housed in the closed inner space of the package, and a catching member located in the closed inner space of the package to catch and hold a foreign matter suspended in an atmosphere in the closed inner space of the package.

### CROSS REFERENCE TO RELATED APPLICATION

This application is based on and incorporates herein by reference Japanese Patent Application No. 2007-249758 filed on Sep. 26, 2007.

### FIELD OF THE INVENTION

The present invention relates to a semiconductor device including a package and a semiconductor chip that has a movable portion and is housed in the package. The present invention also relates to a structure of mounting the semiconductor device to an object and a method of removing a foreign matter from the semiconductor device.

### BACKGROUND OF THE INVENTION

A semiconductor chip such as a capacitive dynamic quantity sensor or a microscanner has a movable portion. If a foreign matter enters the movable portion, the foreign matter may get stuck in the movable portion. In such a case, the movable portion cannot correctly move. Therefore, it is important to remove the foreign matter from the semiconductor chip. However, due to miniaturization and complexity of the semiconductor chip, it is difficult to perfectly remove the foreign matter through a visual inspection.

U.S. Pat. No. 7,045,371 corresponding to JP-A-2005-91031 discloses a method of removing a foreign matter from a capacitive dynamic quantity sensor. According to the method, a drive voltage is intentionally applied between fixed and movable portions of the sensor to force the movable portion to move. In such an approach, a foreign matter hidden below the movable portion emerges. The emerged foreign matter is sucked and thus removed.

By the way, such a semiconductor chip having a movable portion is housed in an enclosed inner space of a package to prevent a foreign matter existing outside the package from entering the movable portion.

However, a foreign matter such as dust produced during manufacture of the package may be left in the package. After the semiconductor chip is housed in the package, the foreign matter left in the package may be suspend in an atmosphere in the package and may enter the movable portion of the semiconductor chip.

### SUMMARY OF THE INVENTION

In view of the above-described problem, it is an object of the present invention to provide a semiconductor device configured to reduce a foreign matter suspended in a package in which a semiconductor chip is housed. It is another object of the present invention to provide a structure of mounting the semiconductor device to an object in such a manner to prevent the foreign matter from entering a movable portion of the semiconductor device. It is further another object of the present invention to provide a method of removing the foreign matter from the semiconductor device.

According to a first aspect of the present invention, a semiconductor device includes a package, a semiconductor chip, and a catching member. The package defines a closed inner space. The semiconductor chip has a movable portion on one side and is housed in the closed inner space of the package. The catching member is exposed to the closed inner space of the package and separated from the movable portion of the semiconductor chip by a predetermined distance. The catching member is configured to catch and hold a foreign matter suspended in an atmosphere in the closed inner space of the package. Preferably, the catching member can be a sticky member configured to catch and hold the foreign matter by sticky force. In a structure of mounting the semiconductor device to an object, the sticky member can be located below the movable portion of the semiconductor chip in a vertical direction. Preferably, the catching member can include a voltage source configured to apply a voltage to an electrically conductive lid of the package so as to cause the lid to catch and hold the foreign matter by electrostatic force. In a structure of mounting the semiconductor device to an object, the electrically conductive lid can be located below the movable portion of the semiconductor chip in a vertical direction.

According to a second aspect of the present invention, a method of removing a foreign matter from a semiconductor device, which includes a semiconductor chip having a movable portion on one side and housed in a hollow case with a bottom and an opening, includes placing a sticky member on a surface of a lid and covering the opening of the case with the lid such that the sticky member is located inside the case. The method further includes positioning the semiconductor device such that the lid is located below the semiconductor chip in a vertical direction and applying a vibration to the case.

According to a third aspect of the present invention, a method of removing a foreign matter from a semiconductor device, which includes a semiconductor chip having a movable portion on one side and housed in an a hollow case with a bottom and an opening, includes covering the opening of the case with a lid having an electrical conductivity and positioning the semiconductor device such that the lid is located below the semiconductor chip in a vertical direction. The method further includes applying a voltage to the lid and applying a vibration to the case during the application of the voltage.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram showing a cross-sectional view of a semiconductor device according to a first embodiment of the present invention;

FIG. 2 is a diagram showing a top view of the semiconductor device of FIG. 1;

FIG. 3 is a diagram showing a cross-sectional view of a structure of mounting the semiconductor device of FIG. 1 to an object;

FIG. 4 is a diagram showing a cross-sectional view of a semiconductor device according to a second embodiment of the present invention;

FIG. 5 is a diagram showing a top view of the semiconductor device of FIG. 4;

FIG. 6 is a diagram showing a cross-sectional view of a semiconductor device according to a third embodiment of the present invention; and

FIG. 7A is a diagram showing a method of removing a foreign matter from a semiconductor device according to a fourth embodiment of the present invention, and FIG. 7B is a diagram showing a replacement of a lid of the semiconductor device of FIG. 7A.

### DETAILED DESCRIPTION OF THE PREFERRED EMBODIMENTS

### First Embodiment

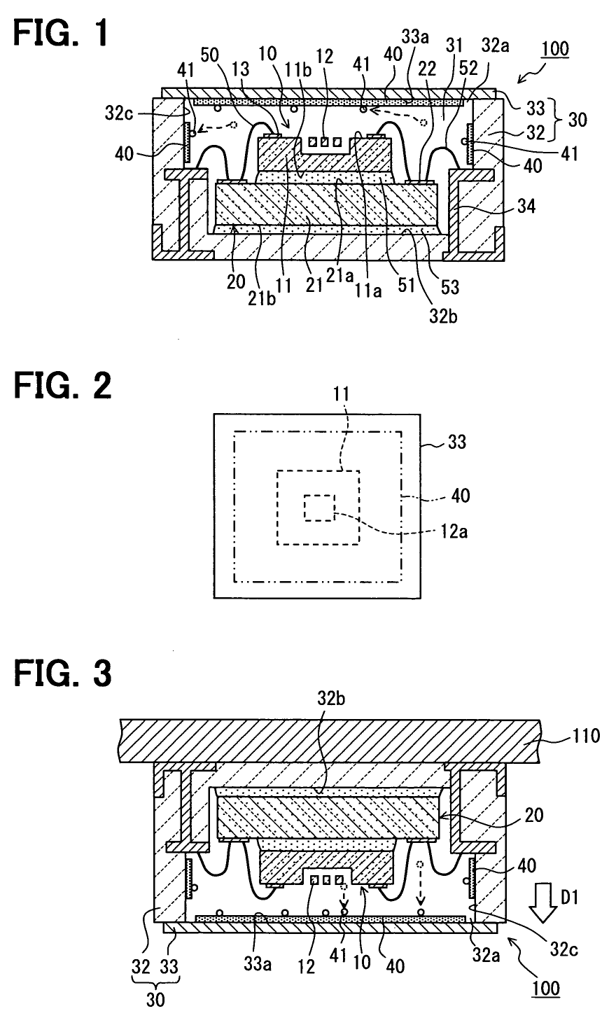

A semiconductor device 100 according to a first embodiment of the present invention is described below with reference to FIGS. 1 and 2. As shown in FIG. 1, the semiconductor device 100 includes a semiconductor chip 10, a circuit chip 20 electrically coupled to the semiconductor chip 10, a package 30 having a closed inner space 31 for housing the semiconductor chip 10 and the circuit chip 20, and a sticky member 40 configured to catch and hold a foreign matter 41 suspended in an atmosphere in the closed inner space 31 by sticky (i.e., adhesive) force. For example, the foreign matter 41 can be waste dust generated in the manufacturing process of the semiconductor device 100. The foreign matter 41 can be fine particles of metal, silicone, ceramic, resin, and the like, generated in the manufacturing process such as an etching process and a dicing process.

The semiconductor chip 10 is made by forming a movable portion 12 on a first surface 11a of a semiconductor substrate 11 by microelectromechanical systems (MEMS) techniques. The semiconductor substrate 11 may be, for example, a silicon-on-insulator (SOI) substrate. In the first embodiment, the semiconductor chip 10 has a rectangular shape and is configured as a capacitive angular velocity sensor chip. A comb structure constructed with the movable portion 12 and a fixed portion is formed on the first surface 11a of the semiconductor substrate 11. The movable portion 12 moves in accordance with applied angular velocity. A capacitance of the comb structure changes with the movement of the movable portion 12. The semiconductor chip 10 detects the applied angular velocity by detecting the capacitance change.

An electrode pad 13 is formed on the first surface 11a of the semiconductor substrate 11 of the semiconductor chip 10. The electrode pad 13 is located around the movable portion 12 and made of gold, aluminum, or the like. The semiconductor chip 10 receives a drive signal for driving the movable portion 12 through the electrode pad 13 and outputs a detection signal indicating the detected capacitance change through the electrode pad 13.

The semiconductor chip 10 is placed on the circuit chip 20 and electrically coupled to the circuit chip 20 through a bonding wire 50.

The circuit chip 20 is made by forming a processing circuit (not shown) into a semiconductor substrate 21 by a well-known semiconductor fabrication process. The processing circuit is constructed with a switching element (e.g., MOSFET), a resistor, a capacitor, and the like. In the first embodiment, the processing circuit is configured to supply the drive signal to the semiconductor chip 10 and perform predetermined proceeding (e.g., capacitance-voltage conversion and amplification) on the detection signal received from the semiconductor chip 10.

A second surface 11b opposite to the first surface 11a of the semiconductor substrate 11 of the semiconductor chip 10 is placed on a first surface 21a of the semiconductor substrate 21 of the circuit chip 20. Specifically, an adhesive 51 is partially or fully interposed between the second surface 11b and the first surface 21a so that the semiconductor chip 10 can be fixed to the circuit chip 20 through the adhesive 51. The first surface 21a of the circuit chip 20 has a larger area than each of the first and second surfaces 11a, 11b of the semiconductor chip 10 so that an outer edge of the semiconductor chip 10 can be located inside an outer edge of the circuit chip 20. An electrode pad 22 is formed on the first surface 21a of the circuit chip 20 around the adhesive 51 (i.e., semiconductor chip 10). For example, the electrode pad 22 is made of aluminum and electrically coupled to the electrode pad 13 of the semiconductor chip 10 through the bonding wire 50. Further, the electrode pad 22 is electrically coupled to a wiring member 34 through a bonding wire 52. A second surface 21b opposite to the first surface 21a of the semiconductor substrate 21 of the circuit chip 20 is placed on the package 30.

The package 30 includes a hollow case 32 and a lid 33. The case 32 has an opening 32a and a bottom. The opening 32a of the case 32 is covered with the lid 33 so that the package 30 can have the closed inner space 31, where the semiconductor chip 10 and the circuit chip 20 are housed.

The case 32 can be made of ceramics, resin, or the like. In the first embodiment, the case 32 is made of ceramics such as alumina and configured as a multilayer ceramic wiring board. The wiring member 34 is integrally formed with the case 32 in such a manner the wiring member 34 has a first portion exposed to the closed inner space 31 of the package 30 and a second portion exposed outside the package 30. The first portion of the wiring member 34 is electrically coupled to the bonding wire 52. An output signal of the circuit chip 20 is transmitted to external circuitry through the bonding wire 52 and the wiring member 34.

The circuit chip 20 is fixed to an inner bottom surface 32b of the case 32 through an adhesive 53. Specifically, the adhesive 53 is interposed between the second surface 21b of the circuit chip 20 and the bottom surface 32b of the case 32.

The lid 33 can be made of ceramics, resin, metal, or the like. The lid 33 is fixed to the case 32 by brazing, welding, adhesive, or the like. Thus, the opening 32a of the case 32 is covered with the lid 33 so that the package 30 can have the closed inner space 31.

The sticky member 40 is placed in the closed inner space 31 to catch the foreign matter 41 suspended in the atmosphere in the closed inner space 31. The sticky member 40 is distanced from the movable portion 12 not to interfere with the movement of the movable portion 12. The sticky member 40 has an sticky (i.e., adhesion) property and can be made of a well-known sticky material such as rubber, synthetic resin, glue or the like. The sticky member 40 can immediately stick to other things at room temperature at low pressure. The sticky property of the sticky member 40 is maintained even after the sticky member 40 sticks to other things.

Specifically, the sticky member 40 is placed on each of an inner surface 32c of the case 32 and a back surface 33a of the lid 33. As shown in FIG. 2, the sticky member 40 on the back surface 33a of the lid 33 has a larger area than a movable region 12a where the movable portion 12 of the semiconductor chip 10 is formed. Therefore, an outer edge of the movable region 12a can be located inside an outer edge of the sticky member 40 on the back surface 33a of the lid 33. In the first embodiment, the sticky member 40 on the back surface 33a of the lid 33 has a larger area than the first surface 11a of the semiconductor chip 10 (i.e., the semiconductor substrate 11) so that the outer edge of the semiconductor chip 10 can be located inside the outer edge of the sticky member 40 on the back surface 33a of the lid 33.

For example, the semiconductor device 100 according to the first embodiment can be made as follows. Firstly, the semiconductor chip 10, the circuit chip 20, and the package 30 are prepared. The sticky member 40 is placed on the inner surface of the package 30 in advance. Then, the adhesive 53 is applied to at least one of the bottom surface 32b of the case 32 and the second surface 21b of the circuit chip 20. Then, the second surface 21b of the circuit chip 20 is placed on the bottom surface 32b of the case 32 so that the circuit chip 20 can be fixed to the case 32 through the adhesive 53. Then, the adhesive 51 is applied to at least one of the second surface 11b of the semiconductor chip 10 and the first surface 21a of the circuit chip 20. Then, the second surface 11b of the semiconductor chip 10 is placed on the first surface 21a of the circuit chip 20 so that the semiconductor chip 10 can be fixed to the circuit chip 20 through the adhesive 51. Then, the electrode pad 13 of the semiconductor chip 10 is electrically coupled to the electrode pad 22 of the circuit chip 20 through the bonding wire 50. Further, the electrode pad 22 of the circuit chip 20 is electrically coupled to the wiring member 34 of the case 32 through the bonding wire 52. Then, the lid 33 is fixed to the case 32 so that the opening 32a of the case 32 can be covered with the lid 33. Thus, the semiconductor device 100 is completed.

In the above example, the electrode pad 22 of the circuit chip 20 is electrically coupled to the wiring member 34 of the case 32 through the bonding wire 52, after the semiconductor chip 10 is fixed to the circuit chip 20. Alternatively, the electrode pad 22 can be electrically coupled to the wiring member 34 through the bonding wire 52, before the semiconductor chip 10 is fixed to the circuit chip 20. The sticky member 40 can be placed on the inner surface of the package 30 at any time before the lid 33 is fixed to the case 32.

As described above, according to the first embodiment, the semiconductor device 100 includes the sticky member 40. The sticky member 40 is placed on the inner surface of the package 30 and exposed to the closed inner space 31, where the semiconductor chip 10 and the circuit chip 20 are housed. For example, when the package 30 is subjected to external force or temperature change, airflow occurs in the closed inner space 31 of the package 30. The airflow causes the foreign matter 41 left in the package 30 to be suspended in the atmosphere in the closed inner space 31. As indicated by a broken arrow in FIG. 1, the suspended foreign matter 41 is hit against the sticky member 40 and stuck to the sticky member 40. The sticky member 40 catches and holds the foreign matter 41 suspended in the atmosphere in the closed inner space 31 so as to prevent the foreign matter 41 from entering the movable portion 12 of the semiconductor chip 10. In summary, the sticky member 40 serves as an adsorbent.

Since the sticky member 40 has the sticky property, the sticky member 40 can not only catch the foreign matter 41 but also stick to the inner surface of the package 30. That is, the sticky member 40 can be placed and fixed on the inner surface of the package 30 without an additional fixing member (e.g., a screw). Therefore, the sticky member 40 can have a simple structure and a large (surface) area without interfering with the movable portion 12 and the bonding wires 50, 52. Thus, the sticky member 40 can catch and hold the foreign matter 41 effectively.

The semiconductor chip 10 is fixed to the bottom surface 32b of the case 32 across the circuit chip 20 in such a manner that the movable portion 12 formed on the first surface 11a of the semiconductor chip 10 can face the sticky member 40 on the back surface 33a of the lid 33. The sticky member 40 on the back surface 33a of the lid 33 has a larger area than the first surface 11a of the semiconductor chip 10 so that the outer edge of the semiconductor chip 10 can be located inside the outer edge of the sticky member 40 on the back surface 33a of the lid 33. In such an approach, the sticky member 40 can surely catch and hold the foreign matter 41 suspended in the atmosphere above the movable portion 12, thereby preventing the foreign matter 41 from entering the movable portion 12.

The first embodiment described above can be modified in various ways. For example, the circuit chip 20 can be eliminated from the semiconductor device 100.

The sticky member 40 can be placed on a portion other than the surfaces 32c, 33a of the package 30, as long as the sticky member 40 is exposed to the closed inner space 31 and distanced from the movable portion 12. For example, the sticky member 40 can be placed on at least one of the bottom surface 32b of the case 32, the first surface 11a of the semiconductor chip 10, the first surface 21a of the circuit chip 20, a side surface of the semiconductor chip 10, and a side surface of the circuit chip 20.

As shown in FIG. 3, the semiconductor device 100 can be mounted on a object 110 (e.g., vehicle) to measure angular velocity of the object 110. It is preferable that the semiconductor device 100 be mounted to the object 110 in such a manner that the sticky member 40 can be located below the movable portion 12 in a vertical direction D1. In FIG. 3, the semiconductor device 100 is mounted to the object 110 in such a manner that the lid 33 is located below the semiconductor chip 10 in the vertical direction D1. Thus, the sticky member 40 on the back surface 33a of the lid 33 is located below the movable portion 12 of the semiconductor chip 10 in the vertical direction D1. In such an approach, as indicated by a broken arrow in FIG. 3, the sticky member 40 can surely catch and hold the foreign matter 41 falling due to gravity. Thus, the foreign matter 41 suspended in the atmosphere in the closed inner space 31 can be reduced efficiently.

### Second Embodiment

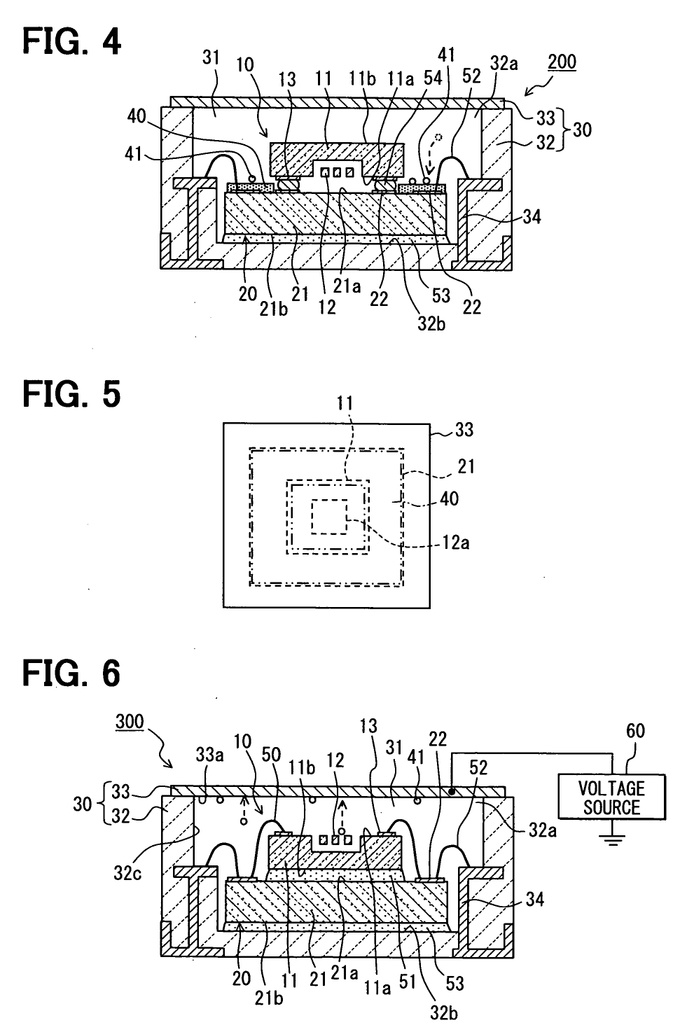

A semiconductor device 200 according to a second embodiment of the present invention is described below with reference to FIGS. 4, 5. A difference between the first and second embodiments is as follows.

In the first embodiment, the movable portion 12 of the semiconductor chip 10 faces the back surface 33a of the lid 33 of the package 30, and the sticky member 40 is placed on the back surface 33a of the lid 33.

In the second embodiment, as shown in FIG. 4, the semiconductor chip 10 is placed on the circuit chip 20 in such a manner that the movable portion 12 of the semiconductor chip 10 can face the first surface 21a of the circuit chip 20. The electrode pad 13 formed on the first surface 11a of the semiconductor chip 10 is electrically coupled to the electrode pad 22 formed on the first surface 21a of the circuit chip 20 though a solder bump 54. The sticky member 40 is placed on the first surface 21a of the circuit chip 20 around the semiconductor chip 10.

Specifically, as shown in FIG. 5, the sticky member 40 has a rectangular ring shape and surrounds facing area between the semiconductor chip 10 and the circuit chip 20. Thus, the movable portion 12 (i.e., movable region 12a) of the semiconductor chip 10 is surrounded by the sticky member 40. More specifically, an inner edge of the sticky member 40 is located inside an outer edge of the facing area between the semiconductor chip 10 and the circuit chip 20 and located close to the solder bump 54. An outer edge of the sticky member 40 is substantially aligned with an outer edge of the first surface 21a of the circuit chip 20. Therefore, as shown in FIG. 4, the electrode pad 22 electrically coupled to the wiring member 34 through the bonding wire 52 is covered (e.g., encapsulated) with the sticky member 40. The sticky member 40 is separated from the first surface 11a of the semiconductor chip 10 so that the movable portion 12 can be exposed to the atmosphere in the closed inner space 31.

The sticky member 40 is placed on the first surface 21a of the circuit chip 20, after the electrode pad 22 is electrically coupled to the wiring member 34 through the bonding wire 52. Thus, the electrode pad 22 electrically coupled to the wiring member 34 through the bonding wire 52 can be covered with the sticky member 40.

As described above, according the second embodiment, the semiconductor device 200 includes the sticky member 40. Like the first embodiment, the sticky member 40 catches and holds the foreign matter 41 suspended in the atmosphere in the closed inner space 31 so as to prevent the foreign matter 41 from entering the movable portion 12 of the semiconductor chip 10.

Since the sticky member 40 can not only catch the foreign matter 41 but also stick to the first surface 21a of the circuit chip 20, the sticky member 40 can be placed and fixed on the first surface 21a of the circuit chip 20 without the additional fixing member. Therefore, the semiconductor device 200 can have a simple structure.

The semiconductor chip 10 is placed on the circuit chip 20 in such a manner that the movable portion 12 of the semiconductor chip 10 can face the first surface 21a of the circuit chip 20. Therefore, the foreign matter 41 cannot reach the movable portion 12 without passing through the facing area between the semiconductor chip 10 and the circuit chip 20. As a result, the possibility that the foreign matter 41 enters the movable portion 12 can be greatly reduced.

The sticky member 40 is placed on the first surface 21a of the circuit chip 20. Therefore, before the foreign matter 41 reaches the movable portion 12 by passing through the facing area, the sticky member 40 can catch and hold the foreign matter 41. Thus, the foreign matter 41 suspended in the atmosphere in the closed inner space 31 can be effectively reduced.

The sticky member 40 is partially placed inside the facing area and surrounds the movable portion 12 of the semiconductor chip 10. In such an approach, the sticky member 40 can surely catch and hold the foreign matter 41 so as to prevent the foreign matter 41 from entering the movable portion 12.

The sticky member 40 is placed on the first surface 21a of the circuit chip 20 in such a manner that the sticky member 40 can be separated from the first surface 11a of the semiconductor chip 10. That is, the facing area between the semiconductor chip 10 and the circuit chip 20 is not sealed by the sticky member 40. In such an approach, the movable portion 12 is exposed to the atmosphere in the closed inner space 31 so that the temperature change (e.g., increase) in the movable portion 12 can be relieved.

The second embodiment described above can be modified in various ways. For example, the sticky member 40 can be placed to fully cover the first surface 21a of the circuit chip 20. The sticky member 40 can have a shape other than a rectangular ring shape. For example, the sticky member 40 can include a plurality of sticky members arranged in a predetermined pattern.

It is preferable that the semiconductor device 200 be mounted to the object in such a manner that the sticky member 40 can be located below the movable portion 12 in a vertical direction. In such an approach, the sticky member 40 can surely catch and hold the foreign matter 41 falling due to gravity. Thus, the foreign matter 41 suspended in the atmosphere in the closed inner space 31 can be reduced efficiently.

The sticky member 40 can be placed on a portion other than the first surface 21a of the circuit chip 20. For example, in addition to or instead of the first surface 21a, the sticky member 40 can be placed on the side surface of the circuit chip 20. Further, the sticky member 40 can be placed on at least one of the first surface 11a, the second surface 11b, and the side surface of the semiconductor chip 10. Furthermore, the sticky member 40 can be placed on the inner surface of the package 30.

### Third Embodiment

A semiconductor device 300 according to a third embodiment of the present invention is described below with reference to FIG. 6. A difference between the first and third embodiments is as follows.

As can be seen by comparing FIGS. 1 and 6, the semiconductor device 300 has no sticky member 40. The lid 33 of the package 30 of the semiconductor device 300 is made of an electrically conductive material such as metal. A voltage source (e.g., direct-current power supply) 60 is electrically coupled to the lid 33 and configured to apply a predetermined voltage to the lid 33.

When the voltage source 60 applies the voltage to the lid 33, the lid 33 becomes charged. If the foreign matter 41 left in the package 30 is a dielectric material such as ceramic or resin, the foreign matter 41 is polarized (i.e., becomes a dipole) due to an electric field caused by the charged lid 33. As a result, the foreign matter 41 is electrostatically attracted to the charged lid 33 and stuck to the back surface 33a of the lid 33. In this way, the charged lid 33 catches and holds the foreign matter 41 left in the package 30.

As described above according to the third embodiment, the lid 33 and the voltage source 60 work in conjunction with each other to serve as a catching member (i.e., adsorbent) to catch and hold the foreign matter 41. After the semiconductor chip 10 is housed in the package 30, the voltage source 60 applies the voltage to the lid 33 so that the foreign matter 41 in the package 30 can be attracted to the lid 33. In this way, the lid 33 catches and holds the foreign matter 41 so as to prevent the foreign matter 41 from entering the movable portion 12 of the semiconductor chip 10.

When the case 32 is made of a dielectric material (e.g., ceramic), it is likely that a dielectric dust as the foreign matter 41 is left in the package 30, after the semiconductor chip 10 is housed in the package 30. The dielectric dust 41 can be removed by applying the voltage to the lid 33 using the voltage source 60. Therefore, the semiconductor device 300 according to the third embodiment can be effectively used, when the case 32 is made of a dielectric material.

The lid 33 is located to face the movable portion 12 of the semiconductor chip 10. In such an approach, the lid 33 can surely catch and hold the foreign matter 41 suspended in the atmosphere above the movable portion 12. Thus, the possibility that the foreign matter 41 enters the movable portion 12 can be greatly reduced.

The third embodiment described above can be modified in various ways. For example, the case 32 can be made of a dielectric material other than ceramic. When the case 32 is made of resin, the case 32 can be electrically insulated from the lid 33.

The circuit chip 20 can be eliminated from the semiconductor device 300 and provided as an external component.

The voltage source 60 can apply the voltage to the lid 33 at any time, after the semiconductor chip 10 is housed in the package 30 by attaching the lid 33 to the case 32. Once the foreign matter 41 is stuck to the back surface 33a of the lid 33 by the application of the voltage, the foreign matter 41 remains stuck to the back surface 33a of the lid 33 even after the voltage application to the lid 33 is stopped. Therefore, the foreign matter 41 in the package 30 can be removed by applying the voltage to the lid 33 instantaneously, continuously, or periodically, after the lid 33 is attached to the case 32.

The third embodiment can be combined with each of the first and second embodiments. For example, the semiconductor device 300 of the third embodiment can include the sticky member 40 described in the first embodiment. Like the first embodiment, the sticky member 40 can be placed on the back surface 33a of the lid 33 and the inner surface 32c of the case 32. For another example, the semiconductor 200 of the second embodiment can include the lid 33 made of a conductive material and the voltage source 60 described in the third embodiment. In such an approach, the foreign matter 41 in the package 30 can be removed effectively.

It is preferable that the semiconductor device 300 be mounted to the object in such a manner that the lid 33 can be located below the movable portion 12 in a vertical direction. In such an approach, the foreign matter 41 in the package 30 can be attracted and stuck to the back surface 33a of the lid 33 not only by electrostatic force but also by gravity. Thus, the foreign matter 41 suspended in the atmosphere in the package 30 can be removed effectively.

### Fourth Embodiment

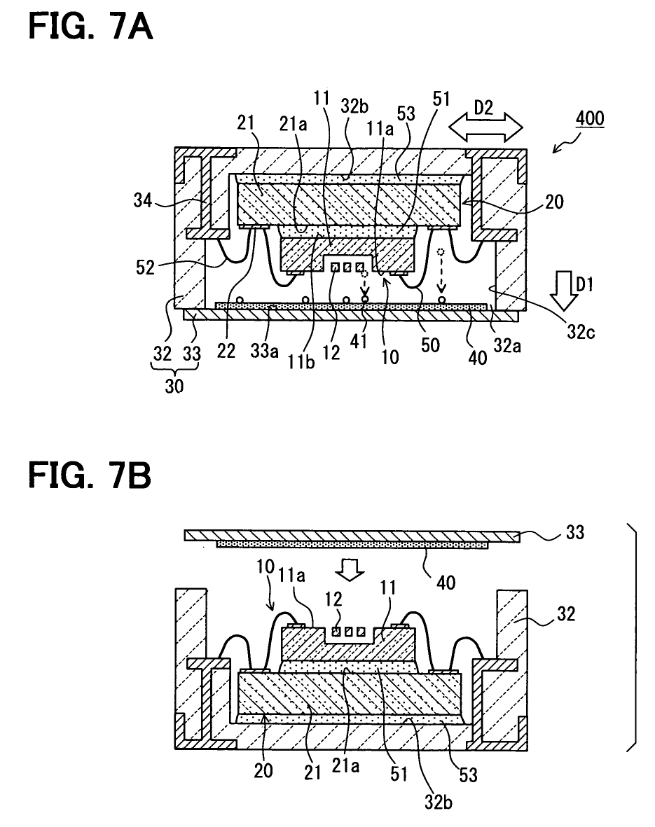

A foreign matter removing method according to a fourth embodiment of the present invention is described below with reference to FIGS. 7A, 7B. The foreign matter 41 caught by the sticky member 40 or the charged lid 33 described in the preceding embodiments can be removed outside the package 30 using the removing method.

A difference between the semiconductor device 100 shown in FIG. 1 and a semiconductor device 400 shown in FIG. 7A is in that the semiconductor device 400 does not have the sticky member 40 on the inner surface 32c of the case 32. That is, the semiconductor device 400 has only the sticky member 40 on the back surface 33a of the lid 33.

Firstly, the semiconductor device 400 is positioned such that the lid 33 can be located below the movable portion 12 of the semiconductor chip 10 in the vertical direction D1. Then, vibration is applied to the case 32 in a horizontal direction D2. As indicated by a broken arrow in FIG. 7A, due to the vibration and gravity, the foreign matter 41 in the movable portion 12 or suspended in the closed inner space 31 falls on the sticky member 40 on the back surface 33a of the lid 33. Thus, the foreign matter 41 left in the package 30 is caught and held by the sticky member 40 on the lid 33. As a result, the foreign matter 41 in the package 30 can be reduced.

It is preferable that the semiconductor chip 10 be fixed to the bottom surface 32b of the case 32 (through the circuit chip 20) as shown in FIG. 7A. In such an approach, the lid 33 can be located directly below the movable portion 12 of the semiconductor chip 10 so that the foreign matter 41 can surely fall on the sticky member 40 on the back surface 33a of the lid 33. The semiconductor chip 10 can be fixed to a portion other than the bottom surface 32b, as long as the lid 33 can be located below the movable portion 12 of the semiconductor chip 10. For example, the semiconductor chip 10 can be fixed to the inner surface 32c.

As shown in FIG. 7B, the lid 33 having the sticky member 40 holding the foreign matter 41 is replaced with new lid 33. In such an approach, the foreign matter 41 is removed outside the package 30 so that the foreign matter 41 left in the package 30 can be surely reduced. In FIG. 7b, the new lid 33 has new sticky member 40. In such an approach, the foreign matter 41 still left in the package 30 can be removed using the new sticky member 40. Alternatively, the new lid 33 can have no sticky member 40.

In this way, the removing method according to the fourth embodiment is applied to the semiconductor device 400 having the sticky member 40 on the inner surface 32c of the case 32. The removing method can be applied to each of the semiconductor devices 100, 200, and 300 of the first, second, and third embodiments in the same way as applied to the semiconductor device 400.

(Modifications)

The embodiments described above can be modified in various ways. The semiconductor chip 10 can be a semiconductor chip other than a capacitive angular velocity sensor chip. For example, the semiconductor chip 10 can be a dynamic quantity sensor chip (e.g., capacitive acceleration sensor chip) or an optical device chip (e.g., microscanner with a static actuator) made by MEMS techniques.

Such changes and modifications are to be understood as being within the scope of the present invention as defined by the appended claims.

What is claimed is:

1. A semiconductor device comprising:
a package defining a closed inner space;
a semiconductor chip housed in the closed inner space of the package and having first and second sides opposite each other, the semiconductor chip including a movable portion on the first side; and
a catching member exposed to the closed inner space of the package and separated from the movable portion of the semiconductor chip by a predetermined distance,
wherein the catching member is configured to catch and hold a foreign matter in the closed inner space of the package.

2. The semiconductor device according to claim 1,
wherein the catching member is a sticky member configured to catch and hold the foreign matter by sticky force.

3. The semiconductor device according to claim 2,
wherein the sticky member is fixed to an inner surface of the package.

4. The semiconductor device according to claim 3,
wherein the second side of the semiconductor chip is fixed to the inner surface of the package such that the movable portion of the semiconductor chip faces the sticky member.

5. The semiconductor device according to claim 2, further comprising:
a circuit chip housed in the closed inner space of the package and having first and second sides opposite each other,
wherein the semiconductor chip and the circuit chip are coupled together through a solder bump such that the movable portion of the semiconductor chip faces the first side of the circuit chip, and
wherein the second side of the circuit chip is fixed to the inner surface of the package.

6. The semiconductor device according to claim 5,
wherein the sticky member is fixed to the first side of the circuit chip.

7. The semiconductor device according to claim 6,
wherein the sticky member is placed near a periphery of a facing area between the semiconductor chip and the circuit chip to surround the movable portion of the semiconductor chip.

8. The semiconductor device according to claim 6,
wherein the movable portion is exposed to an atmosphere in the closed inner space of the package.

9. The semiconductor device according to claim 1,
wherein the package includes a hollow case and a lid, the case having an opening and a bottom, the lid being made of an electrically conductive material and configured to cover the opening of the case to define the closed inner space, and
wherein the catching member includes a voltage source configured to apply a voltage to the lid so as to cause the lid to catch and hold the foreign matter by electrostatic force.

10. The semiconductor device according to claim 9,
wherein the case is made of a dielectric material.

11. The semiconductor device according to claim 1,
wherein the semiconductor chip is configured to detect a dynamic quantity.

12. A structure of mounting the semiconductor device of claim 2 to an object,
wherein the sticky member is located below the movable portion of the semiconductor chip in a vertical direction.

13. A structure of mounting the semiconductor device of claim 9 to an object,
wherein the lid is located below the movable portion of the semiconductor chip in a vertical direction.

14. A method of removing a foreign matter from a semiconductor device, the semiconductor device including a semiconductor chip having a movable portion on one side, the semiconductor chip being housed in a hollow case with a bottom and an opening, the method comprising:
placing a sticky member on a surface of a lid;
covering the opening of the case with the lid such that the sticky member is located inside the case;
positioning the semiconductor device such that the lid is located below the semiconductor chip in a vertical direction; and
applying a vibration to the case.

15. The method according claim 14, further comprising:
fixing the semiconductor chip to an inner surface of the case such that the movable portion of the semiconductor chip faces the lid.

16. The method according claim 14, further comprising:
replacing the lid with new lid after the application of the vibration.

17. A method of removing a foreign matter from a semiconductor device, the semiconductor device including a semiconductor chip having a movable portion on one side, the semiconductor chip being housed in a hollow case with a bottom and an opening, the method comprising:
covering the opening of the case with a lid having an electrical conductivity;
positioning the semiconductor device such that the lid is located below the semiconductor chip in a vertical direction;
applying a voltage to the lid; and
applying a vibration to the case during the application of the voltage.

18. The method according claim 17, further comprising:
fixing the semiconductor chip to an inner surface of the case such that the movable portion of the semiconductor chip faces the lid.

19. The method according claim 17, further comprising:
replacing the lid with new lid after the application of the vibration.
